(19) United States
(12) Patent Application Publication
(10) Pub. No.: US 2018/0182598 A1
(43) Pub. Date: Jun. 28, 2018

(54) Large Sized Showerhead Assembly

(71) Applicant: TES CO., LTD, Yongin (KR)

(72) Inventor: Jae-Hwan Kim, Hwaseong (KR)

(73) Assignee: TES CO., LTD

(21) Appl. No.: 15/848,764

(22) Filed: Dec. 20, 2017

(30) Foreign Application Priority Data
Dec. 23, 2016 (KR) 10-2016-0177583

(51) Int. Cl. H01J 37/32; C23C 16/455; C23C 16/509

(52) U.S. Cl. CPC H01J 37/3244; H01J 37/32477; H01J 37/32091; H01J 2237/3323; C23C 16/5096; H01J 2237/3321; H01J 2237/3325; C23C 16/45565

(57) ABSTRACT

A large sized showerhead assembly and a thin film deposition apparatus including the same are provided. The large sized showerhead assembly includes a backing plate disposed in a chamber, and a showerhead disposed below the backing plate to supply gas toward a substrate, wherein the showerhead is connected to the backing plate to thermally expand.

### CROSS-REFERENCE TO RELATED APPLICATIONS

This application claims priority from Korean Patent Application No. 10-2016-0177583, filed on Dec. 23, 2016, the disclosure of which is incorporated herein by reference in its entirety.

### TECHNICAL BACKGROUND

The present invention relates to a large sized showerhead assembly used in a thin film deposition apparatus.

### RELATED ART

Recently, flat displays have been widely employed as televisions (TVs), computer monitors, or the like as well as personal digital assistants (PDAs) and, here, there are various types of flat displays, for example, a liquid crystal display (LCD), a plasma display panel (PDP), and an organic light emitting diode (OLED). Thereamong, an OLED that is referred to as an organic light emitting diode refers to a “self-emissive organic material” that self-emits light according to an electroluminescence phenomenon whereby light is emitted from a fluorescent organic compound when current flows therein. OLEDs are attracting attention as next generation display devices that are replaceable with a current LCD because not only the OLEDs are driven at a low voltage and are formed in a thin film type, but also have a wide viewing angle and quick response speeds.

A manufacture process of an OLED is broadly classified into a pattern forming process, an organic thin film deposition process, an encapsulation process, an adherence process of adhering a substrate with an organic thin film deposited thereon and a substrate on which the encapsulation process is performed, and so on.

A plasma-enhanced chemical vapor deposition process (hereinafter, PE-CVD) as one of deposition processes is a process of depositing, on a substrate, process gas as a deposition material that is changed to a plasma state by external high-frequency power to achieve high energy. A PE-CVD apparatus for performing the deposition process includes a chamber having a susceptor with a substrate loaded thereon, a backing plate that is provided to function as an electrode in the chamber, and a showerhead that is provided to function as a gas inlet below the backing plate.

The showerhead is spaced apart from the backing plate at a predetermined distance to form a separation space portion between the showerhead and the backing plate. A plurality of through holes with a minute size is formed in a surface of the showerhead. The showerhead is arranged in substantially parallel to the susceptor with a substrate loaded thereon to maintain uniformity of a deposition film deposited on the substrate and an interval between the showerhead and the susceptor is also appropriately adjusted.

When the deposition process is performed, process gas is injected into the chamber to bottom from top through the backing plate, and is diffused through the separation space portion and, then, is ejected through the plurality of through holes formed in the showerhead to form the deposition film on the substrate.

FIG. 10 is a diagram of a connection structure between a backing plate 10 and a showerhead 30 according to a prior art. As shown in FIG. 10, the showerhead 30 is connected to the backing plate 10 by a bolt 20. However, according to the recent trend, a flat display is large-sized and has a large area and, thus, the showerhead 30 also has a large area.

However, the showerhead 30 is heated at relatively high temperature to thermally expand during the deposition process. In this case, a size of the showerhead 30 due to thermal expansion is increased compared with a small-sized showerhead of prior art. In this case, according to the prior art, when the showerhead 30 is fixedly coupled to the backing plate 10 using the bolt 20 or the like, there is no appropriate method for compensating for the volume change due to thermal expansion of the showerhead 30 and, thus, the showerhead 30 is breakable or damaged during thermal expansion.

### SUMMARY

Exemplary embodiments of the present invention overcome the above disadvantages and other disadvantages not described above. Also, the present invention is not required to overcome the disadvantages described above, and an exemplary embodiment of the present invention may not overcome any of the problems described above.

The present invention provides a large sized showerhead assembly and a thin film deposition apparatus including the same, for allowing a volume change due to thermal expansion while fixedly connecting a showerhead, which is large-sized and has a large area connected to a backing plate without sagging.

According to one embodiment of the present invention, a large sized showerhead assembly includes a backing plate disposed in a chamber, and a showerhead disposed below the backing plate to supply gas toward a substrate, wherein the showerhead is connected to the backing plate to thermally expand.

The large sized showerhead assembly may further include a connecting unit that connects the showerhead to the backing plate, and the showerhead comprises an extension member that extends upward along an edge of an upper surface of the showerhead and the extension member is inserted into the connecting unit and the extension member is connected to the connecting unit to thermally expand to support the showerhead.

The connecting unit may connect the extension member to the backing plate in a lateral direction of the backing plate.

The connecting unit may include a groove portion into which the extension member is inserted and which has a greater internal volume than a size of the extension member to allow the extension member to accommodate thermal expansion of the showerhead, and a support which has an end portion fixed to the extension member through a first through hole of a side wall of the backing plate to support the extension member.

The support may include a first support coupled to the extension member in a perpendicular direction thereto and configured to guide a volume change due to thermal expansion of the extension member and a second support coupled to the extension member to be angled therewith at a predetermined angle and configured to prevent the showerhead from sagging.

The support may include a screw or a bolt and has a screw thread that is formed on an end portion of the support and may be coupled to the extension member through a first through hole of the side wall of the backing plate.

The first through hole is formed as a longitudinal hole in a vertical direction.

The support may include a circular or curved head formed on an end portion thereof, and the extension member may include an insertion space with the head inserted thereinto and having a larger volume than a size of the head.

The support may be radially arranged around a central portion of the showerhead.

Radio frequency (RF) power may be applied to the backing plate, and the large sized showerhead assembly may further include a fixing member that is formed on a central portion of the showerhead and connects the backing plate to the showerhead to support the showerhead and to transmit the RF power applied to the backing plate to the showerhead.

The connecting unit may include an opening through which the extension member is disposed and which has a larger volume than a size of the extension member to accommodate thermal expansion of the showerhead, and a support which has an end portion fixed to the extension member through a through hole of a side wall of the backing plate to support the extension member.

The support may include a first support coupled to the extension member in a perpendicular direction thereto and configured to guide a volume change due to thermal expansion of the extension member, and a second support coupled to the extension member to be angled therewith at a predetermined angle and configured to prevent the showerhead from sagging.

The support may include a screw or a bolt and has a screw thread that is formed on an end portion of the support and is coupled to the extension member through a side wall of the backing plate.

The through hole may be formed as a longitudinal hole in a vertical direction.

The support may include a circular or curved head formed on an end portion thereof, and the extension member may include an insertion space with the head inserted thereinto and having a larger volume than a size of the head.

The support may be radially arranged around a central portion of the showerhead.

RF power may be directly applied to the extension member positioned through the opening.

The connecting unit may further include an interval adjuster unit configured to adjust an interval between the showerhead and the substrate.

The interval adjuster unit may include a screw or a bolt and may be coupled to the backing plate through a bottom surface of the showerhead.

The showerhead may include a through hole formed therein, the interval adjuster unit may be coupled to a lower end portion of a side wall of the backing plate through the through hole, and the through hole may be formed as a longitudinal direction in a horizontal direction.

### BRIEF DESCRIPTION OF THE DRAWINGS

The above and/or other aspects of the present invention will be more apparent by describing certain exemplary embodiments of the present invention with reference to the accompanying drawings, in which:

FIG. 1 is a perspective view of a large sized showerhead assembly according to an embodiment of the present invention;

FIG. 2 is a diagram showing a bottom surface of a backing plate of FIG. 1;

FIG. 3 is a side cross-sectional view taken from line of FIG. 1;

FIG. 4 is a transverse cross-sectional view taken from line ‘IV-IV’ of FIG. 1;

FIG. 5 is a diagram showing a support according to another embodiment of the present invention;

FIG. 6 is a coupling perspective view showing a large sized showerhead assembly according to another embodiment of the present invention;

FIG. 7 is an exploded perspective view of FIG. 6;

FIG. 8 is a side cross-sectional view taken along line ‘VIII-VIII’ of FIG. 6;

FIG. 9 is a transverse cross-sectional view taken along line ‘IX-IX’ of FIG. 6; and

FIG. 10 is a diagram a connection structure between a backing plate and a showerhead according to the prior art.

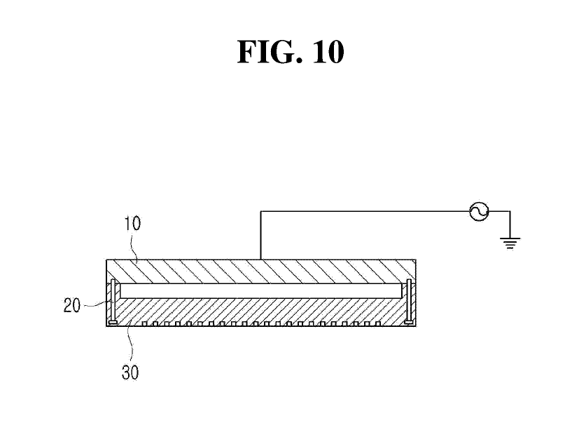

### DETAILED DESCRIPTION

A large sized showerhead assembly according to exemplary embodiments of the present invention will now be described in greater detail with reference to the accompanying drawings.

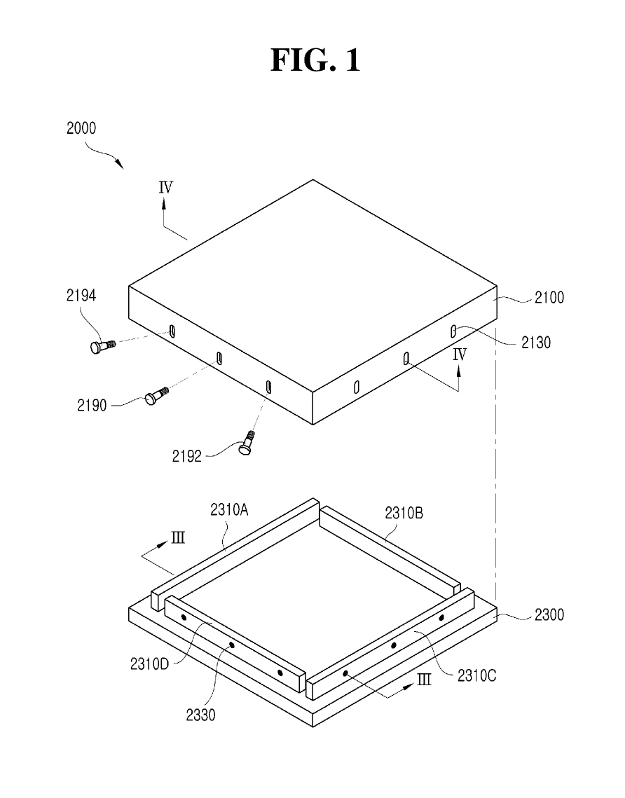

FIG. 1 is a perspective view of a large sized showerhead assembly 2000 according to an embodiment of the present invention.

Referring to FIG. 1, the large sized showerhead assembly 2000 may include a backing plate 2100 disposed in a chamber (not shown) and a showerhead 2300 that is disposed below the backing plate 2100 to supply process gas toward a substrate (not shown), and the showerhead 2300 may be connected to the backing plate 2100 to thermally expand. That is, the showerhead 2300 is connected and coupled to the backing plate 2100 despite thermal expansion.

As the size of the substrate increases, a weight of the showerhead 2300 is also increased and, thus, it may be important to connect the showerhead 2300 to the backing plate 2100 without sagging of the showerhead 2300. In addition, the showerhead 2300 is heated at a high temperature during a deposition process and, thus, needs to be connected to the backing plate 2100 to enable a volume change due to thermal expansion.

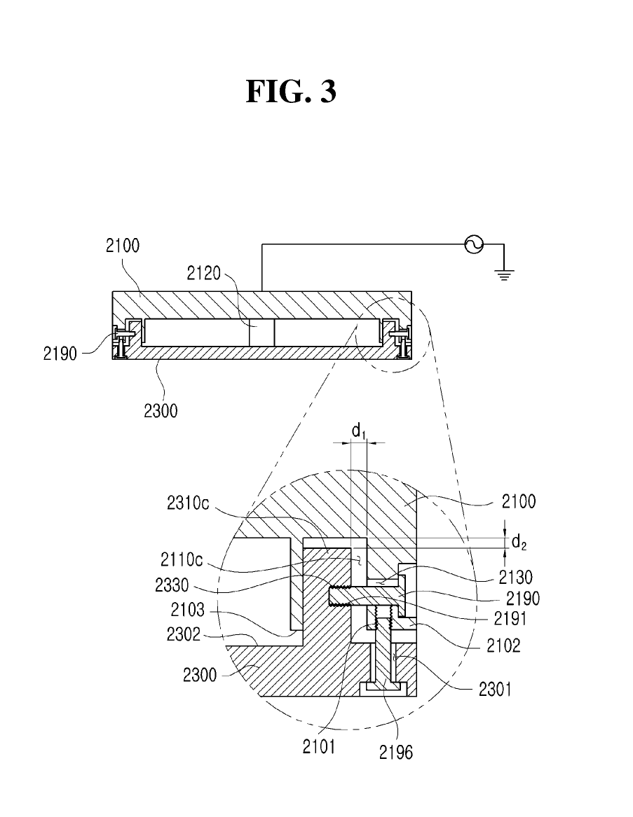

To this end, the large sized showerhead assembly 2000 may further include a connecting unit 2200 (refer to FIG. 3) to connects the showerhead 2300 to the backing plate 2100. In addition, the showerhead 2300 may include extension members 2310A, 2310B, 2310C, and 2310D that extend upward along an edge of an upper surface of the showerhead 2300 and the connecting unit 2200 (refer to FIG. 3) that connects the extension members 2310A, 2310B, 2310C, and 2310D to the backing plate 2100. The extension members 2310A, 2310B, 2310C, and 2310D are inserted into the connecting unit 2200 and the extension members 2310A, 2310B, 2310C, and 2310D are connected to the connecting unit 2200 to thermally expand to support the showerhead 2300.

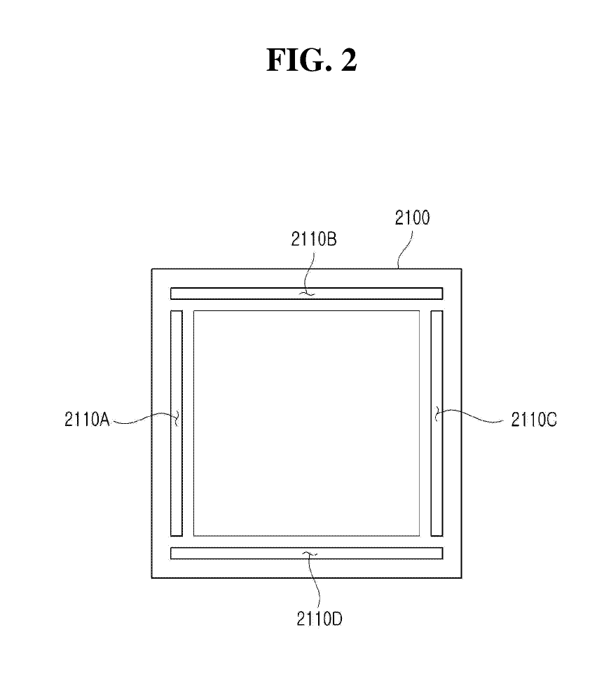

FIG. 2 is a diagram showing a bottom surface of the backing plate 2100 of FIG. 1.

Referring to FIGS. 1 and 2, the connecting unit 2200 (refer to FIG. 3) may connect the extension members 2310A, 2310B, 2310C, and 2310D to the backing plate 2100 in a lateral direction of the backing plate 2100. That is, the large sized showerhead assembly 2000 according to the present embodiment may be configured to connect the showerhead 2300 and the backing plate 2100 to compensate for a volume change due to thermal expansion. In consideration of this point, it is more advantageous to couple the backing plate 2100 in a lateral direction by the connecting unit 2200 than coupling to the backing plate 2100 in a vertical direction to top from bottom like in the prior art, which will be described below in detail.

The connecting unit 2200 may include groove portions 2110A, 2110B, 2110C, and 2110D into which the extension members 2310A, 2310B, 2310C, and 2310D are inserted and which have a greater internal volume than a size of the extension members 2310A, 2310B, 2310C, and 2310D to allow the extension members 2310A, 2310B, 2310C, and 2310D to accommodate thermal expansion of the showerhead 2300, and supports 2190, 2192, and 2194 which have an end portion fixed to the extension members 2310A, 2310B, 2310C, and 2310D through a side wall 2102 (refer to FIG. 3) of the backing plate 2100 to support the extension members 2310A, 2310B, 2310C, and 2310D moveably fixed.

The showerhead 2300 may include the extension members 2310A, 2310B, 2310C, and 2310D that extend a predetermined height along an edge of the showerhead 2300. As shown in FIG. 1, the extension members 2310A, 2310B, 2310C, and 2310D may be formed along the edge of the showerhead 2300 to extend upward. First coupling holes 2330 to which the aforementioned supports 2190, 2192, and 2194 are coupled may be formed in the extension members 2310A, 2310B, 2310C, and 2310D.

The extension members 2310A, 2310B, 2310C, and 2310D may be respectively inserted into and connected to the groove portions 2110A, 2110B, 2110C, and 2110D formed in the bottom surface of the backing plate 2100. In this case, the extension members 2310A, 2310B, 2310C, and 2310D may be connected to the groove portions 2110A, 2110B, 2110C, and 2110D to accommodate thermal expansion when the showerhead 2300 thermally expands.

FIG. 3 is a side cross-sectional view of the large sized showerhead assembly 2000 of FIG. 1 and shows a connection structure between the extension member 2310C and the groove portion 2110C.

Referring to FIG. 3, the extension member 2310C of the showerhead 2300 may be inserted into the groove portion 2110C formed on the bottom surface of the backing plate 2100. In this case, to fix the showerhead 2300 to the backing plate 2100, the support 2190 may be coupled to the first coupling hole 2330 formed in the extension member 2310C through a first through hole 2130 formed in the side wall 2102 of the backing plate 2100.

The support 2190 may be formed as a bolt, a screw, or the like. In this case, as shown in FIG. 3, a screw thread 2191 may be formed on an end portion of the support 2190 to couple the extension member 2310C through the first through holes 2130 of the backing plate 2100.

That is, the support 2190 may not be coupled to the first through hole 2130 formed in the side wall 2102 of the backing plate 2100 but be coupled to the first coupling hole 2330 formed in the extension member 2310C through the first through hole 2130. Accordingly, the support 2190 may be connected to the backing plate 2100 to withstand the weight of the showerhead 2300 and to also allow the extension member 2310C moveably fixed.

That is, when the extension member 2310C is moved due to the thermal expansion of the showerhead 2300, the support 2190 is not coupled to the first through hole 2130 and, thus, the extension member 2310C may become moveable in the groove portion 2110C.

In this case, an internal volume of the groove portion 2110C may be greater than a volume of the extension member 2310C. That is, to provide a space for moving the extension member 2310C, the internal volume of the groove portion 2110C may be greater than the that of the extension member 2310C.

For example, as shown in FIG. 3, when the extension member 2310C of the showerhead 2300 is inserted into the groove portion 2110C formed in the bottom surface of the backing plate 2100, a predetermined space may be formed as a first separation distance d₁ between an external side surface of the extension member 2310C and an internal side surface of the groove portion 2110C. Accordingly, when the showerhead 2300 thermally expands to move the extension member 2310C, the extension member 2310C may be moved in the space formed in the groove portion 2110C.

The end portion of the support 2190 is coupled to the extension member 2310C and, thus, when the large sized showerhead assembly 2000 according to the present embodiment is separated from a chamber and is positioned reversely for maintenance purposes, the showerhead 2300 may be prevented from being separated from the backing plate 2100.

Although one extension member 2310C and one groove portion 2110C have been described above with reference to FIG. 3, the above description may also be applied to the other extension members 2310A, 2310B, and 2310D and the other groove portions 2110A, 2110B, and 2110D.

According to the present embodiment, radio frequency (RF) power may be applied to the backing plate 2100 and, in this regard, the large sized showerhead assembly 2000 may further include a fixing member 2120 that is formed on a central portion of the showerhead 2300 and the fixing member 2120 connects the backing plate 2100 to the showerhead 2300 to support the showerhead 2300 and to transmit the RF power applied to the backing plate 2100 to the showerhead 2300.

The fixing member 2120 may connect the central portion of the showerhead 2300 and the backing plate 2100 to prevent the central portion of the showerhead 2300 from sagging. In this case, when the showerhead 2300 thermally expands, the central portion of the showerhead 2300 is less deformed than other portions and, thus, the fixing member 2120 may be coupled to the central portion via a bolt, etc. like in the prior art.

According to the present embodiment, the connecting unit 2200 between the backing plate 2100 and the showerhead 2300 may include an interval adjuster unit 2196 for adjusting an interval between the showerhead 2300 and a substrate (not shown) below.

The interval adjuster unit 2196 may include a screw or the like. In this case, the interval adjuster unit 2196 may be coupled to the side wall 2102 of the backing plate 2100 through the bottom surface of the showerhead 2300.

In detail, a second coupling hole 2101 may be formed in a lower end portion of the side wall 2102 of the backing plate 2100 in a vertical direction and a second through hole 2301 may be formed in the showerhead 2300. That is, the interval adjuster unit 2196 may be coupled and connected only to the second coupling hole 2101 through the second through hole 2301. In this case, to allow a volume change of the showerhead 2300 due to thermal expansion, the second through hole 2301 may be formed as a longitudinal hole to have a larger internal space in a horizontal direction than the interval adjuster unit 2196 as shown in the drawing. Accordingly, even if the showerhead 2300 thermally expands, the volume change of the showerhead 2300 may be allowed due to the internal space of the second through hole 2301 without interfering with the interval adjuster unit 2196.

When the interval adjuster unit 2196 is fastened to be coupled to the aforementioned second coupling hole 2101, the showerhead 2300 may be moved upward by the interval adjuster unit 2196. In this case, a lower end surface 2103 of the side wall 2102 of the backing plate 2100 may be spaced apart from an upper end surface 2302 of the showerhead 2300 by a predetermined interval and a space with a second separation distance d₂ may be formed between an upper end surface of the extension member 2310C and a ceiling of the groove portion 2110C. Accordingly, the showerhead 2300 may be moved upward without interfering with the backing plate 2100. When the interval adjuster unit 2196 is unfastened, the showerhead 2300 may be moved downward.

Accordingly, the interval adjuster unit 2196 may be fastened or unfastened to narrow or widen an interval between the showerhead 2300 and a substrate.

In this case, to allow the interval adjuster unit 2196 to adjust the interval, the first through hole 2130 of the backing plate 2100 with the aforementioned support 2190 inserted thereinto may be formed in the shape of a longitudinal hole. In the structure shown in FIG. 3, the weight of the showerhead 2300 may be distributed and supported by the support 2190 and the interval adjuster unit 2196, thereby stably supporting the showerhead 2300.

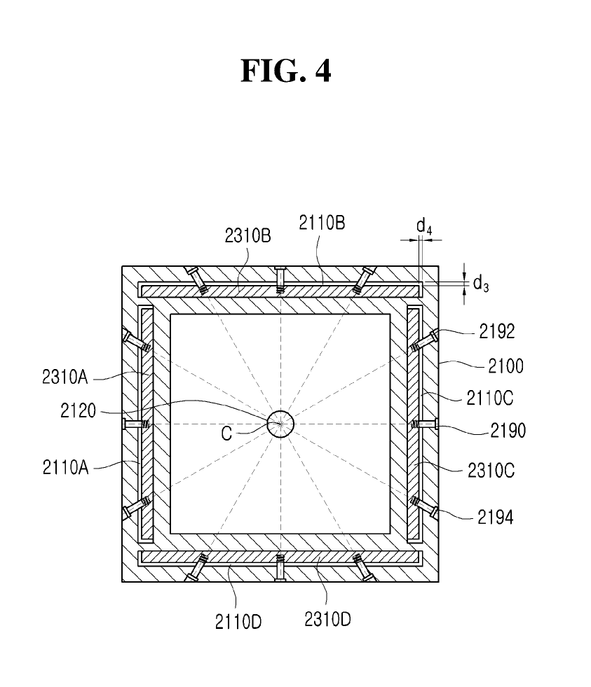

Referring to FIGS. 1 and 4, the first through hole 2130 may be formed in the shape of a longitudinal hole that extends in a vertical direction. Accordingly, when the interval adjuster unit 2196 is rotated, the supports 2190, 2192, and 2194 may be moved up and down a predetermined distance along the first through hole 2130 formed as a longitudinal hole.

Accordingly, the showerhead assembly according to the present embodiment may be configured to adjust an interval between the showerhead 2300 and a substrate by adjustment of the interval adjuster unit 2196 when a thin film deposition apparatus is installed. In addition, when the interval between the showerhead 2300 and the substrate needs to be readjusted after the thin film deposition apparatus is used for a long time, the interval may be easily adjusted by adjustment of the interval adjuster unit 2196.

When the showerhead 2300 thermally expands due to high temperature during a deposition process, deformation increases from the central portion of the showerhead 2300 toward the outer edge of the showerhead 2300 in radial direction. Accordingly, the aforementioned supports 2190, 2192, and 2194 may be arranged in a direction in which the showerhead 2300 thermally expands.

FIG. 4 is a transverse cross-sectional view of the large sized showerhead assembly 2000. For convenience of description of FIG. 4, a support for connecting one extension member 2310C to one groove portion 2110C will be described below.

Referring to FIGS. 1 and 4, the aforementioned support may be classified into a first support 2190 and second supports 2192 and 2194.

When the first support 2190 and the second supports 2192 and 2194 connect the extension member 2310C to the groove portion 2110C moveably fixed, the first support 2190 and the second supports 2192 and 2194 may be radially arranged around a central portion C of the showerhead 2300.

For example, the aforementioned first support 2190 and second supports 2192 and 2194 may be arranged along an imaginary line that radially extends in a radial direction from the central portion C of the showerhead 2300. Accordingly, when deformation increases from the central portion C of the showerhead 2300 toward the outer edge of the showerhead 2300 in radial direction, the extension member 2310C may be prevented from being damaged or deformed by the first support 2190 and the second supports 2192 and 2194.

The first support 2190 and the second supports 2192 and 2194 may guide a volume change due to thermal expansion when showerhead 2300 thermally expands and may also prevent the showerhead 2300 from sagging, but are different in terms of a respective main function.

That is, with regard to the first support 2190 and the second supports 2192 and 2194, the first support 2190 may be coupled to the extension member 2310C in a perpendicular direction thereto and the second supports 2192 and 2194 may be coupled to the extension member 2310C to be angled therewith at a predetermined angle. Accordingly, a main function of the first support 2190 may be guidance of a volume change due to thermal expansion when the showerhead 2300 thermally expands and a main function of the second supports 2192 and 2194 may be prevention of the showerhead 2300 from sagging.

Thus far, although only the supports 2190, 2192, and 2194 for connecting one extension member 2310C to one groove portion 2110C have been described, the present embodiment is not limited thereto and, thus, supports for connecting the other extension members 2310A, 2310B, and 2310D to the groove portions 2110A, 2110B, and 2110D may also be configured.

When the showerhead 2300 is deformed due to thermal expansion, the showerhead 2300 may be deformed in both horizontal and vertical directions. Accordingly, when there is a separation distance between an external side surface of the extension members 2310A, 2310B, 2310C, and 2310D and an internal side surface of the groove portions 2110A, 2110B, 2110C, and 2110D, a fourth separation distance d₄ as well as a third separation distance d₃ may be formed. Accordingly, when one extension member is moved in one groove portion due to thermal expansion, the extension member may be capable of being moved in both horizontal and vertical directions.

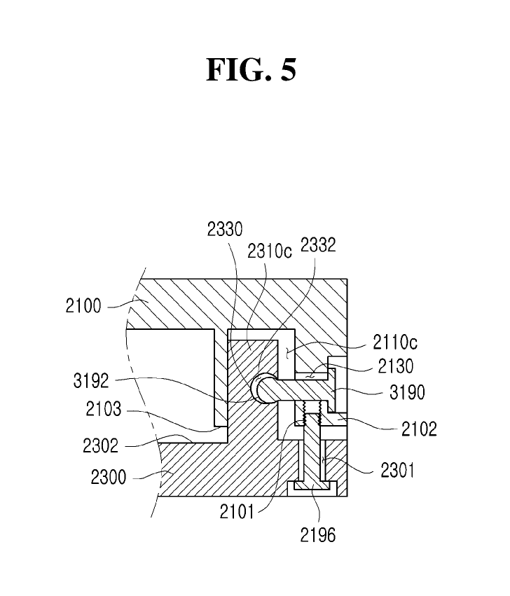

FIG. 5 is a diagram showing a support according to another embodiment of the present invention.

In the aforementioned embodiment, the showerhead may be connected to the backing plate by the support to compensate for a volume change due to thermal expansion of the showerhead. In this case, the aforementioned support may be embodied in the form of a screw or the like and a screw thread of the screw may be coupled to an extension member of the showerhead. In this case, when a size of the showerhead is changed due to thermal expansion, stress may be concentrated on a region to which the screw thread of the screw is coupled, which may deform or damage the screw and/or the extension member of the showerhead. In addition, when the showerhead thermally expands in a vertical direction as well as a horizontal direction, it may not be easy to compensate for a volume change in a vertical direction, in the aforementioned embodiment. Therefore, a connection structure for overcoming such a problem will be described below.

Referring to FIG. 5, a support 3190 according to the present embodiment may include a circular or curved head 3192 formed on an end portion thereof. In addition, the head 3192 may be inserted into the first coupling hole 2330 of the extension member 2310C of the showerhead 2300 and an insertion space 2332 with a larger internal volume than the head 3192 may be formed in the first coupling hole 2330.

Accordingly, according to the present embodiment, the head 3192 of the support 3190 may be arranged to be moved at a predetermined angle in the insertion space 2332 in the first coupling hole 2330 of the extension member 2310C. As a result, when the showerhead 2300 thermally expands in any direction of horizontal and verticals directions, the extension member 2310C and the support 3190 may compensate for a volume change due to thermal expansion.

In this case, the interval adjuster unit 2196, the second through hole 2301, the second coupling hole 2101, and the first through hole 2130 formed as a longitudinal hole are similar to the aforementioned embodiment and, thus, a repeated description is omitted here.

The configuration of the support of FIG. 5 may be applied to an embodiment to be described later as well as the aforementioned embodiment.

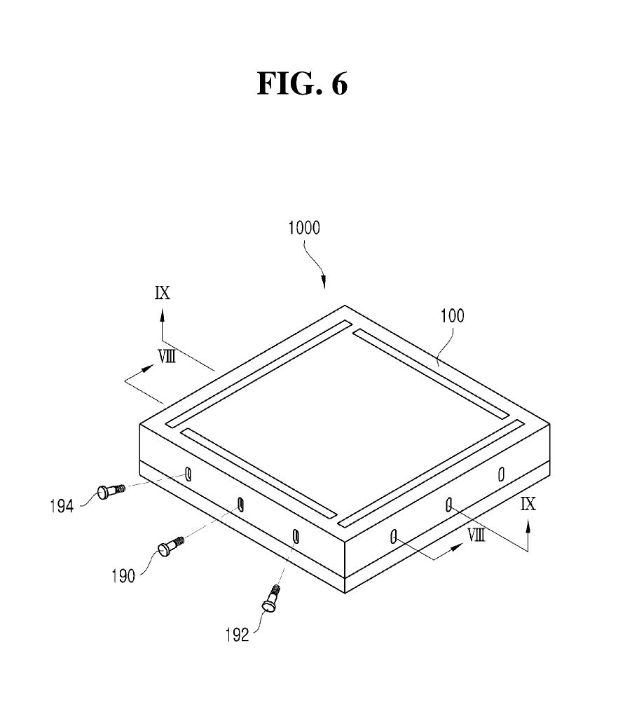

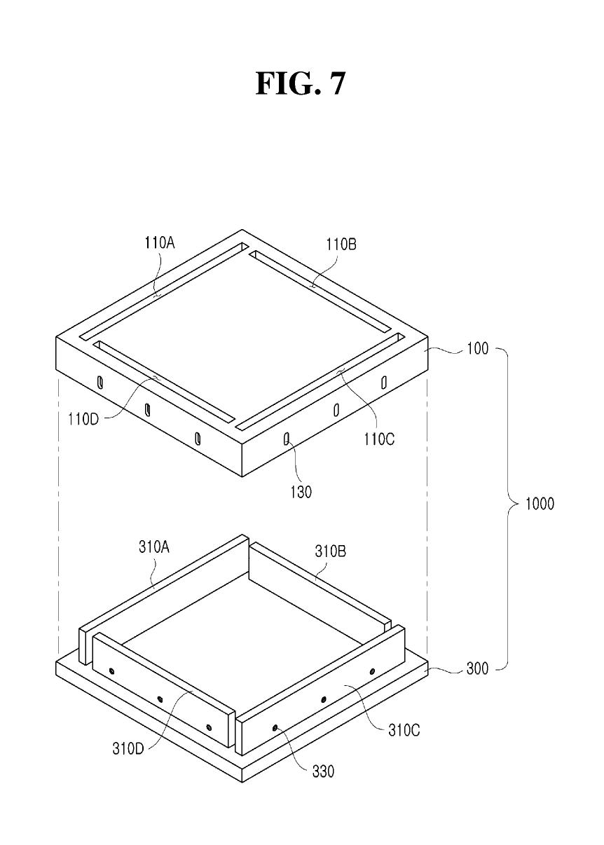

FIG. 6 is a coupled perspective view showing a large sized showerhead assembly 1000 according to another embodiment of the present invention. FIG. 7 is an exploded perspective view of FIG. 6.

Referring to FIGS. 6 and 7, the showerhead assembly 1000 may include a backing plate 100 disposed in a chamber (not shown) and a showerhead 300 disposed below the backing plate 100 to supply process gas toward a substrate (not shown), and the showerhead 300 may be connected to the backing plate 100 to thermally expand.

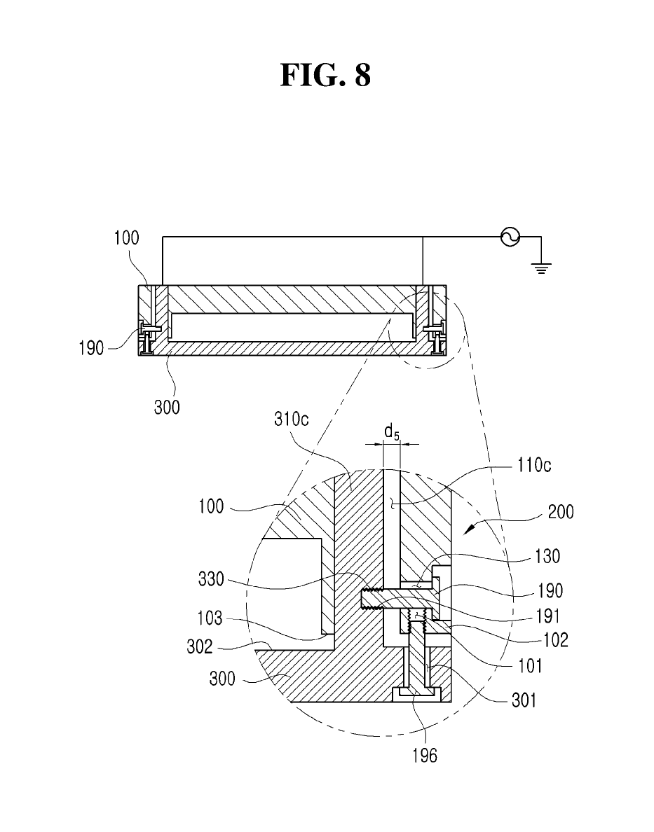

To this end, the showerhead assembly 1000 may include extension members 310A, 310B, 310C, and 310D that extend upward along an edge of an upper surface of the showerhead 300 and a connecting unit 200 (refer to FIG. 8) that connects the extension members 310A, 310B, 310C, and 310D to the backing plate 100. The extension members 310A, 310B, 310C, and 310D are inserted into the connecting unit 200 and the extension members 310A, 310B, 310C, and 310D are connected to the connecting unit 200 to thermally expand to support the showerhead 300.

The connecting unit 200 may include openings 110A, 110B, 110C, and 110D through which the extension members 310A, 310B, 310C, and 310D are disposed and which have a larger volume than a size of the extension members 310A, 310B, 310C, and 310D to accommodate thermal expansion of the showerhead 300, and supports 190, 192, and 194 which have an end portion fixed to the extension members 310A, 310B, 310C, and 310D through a side wall 102 (refer to FIG. 8) of the backing plate 100 to support the extension members 310A, 310B, 310C, and 310D moveably fixed.

The showerhead 300 may include the extension members 310A, 310B, 310C, and 310D that extend a predetermined height along an edge of the showerhead 300. As shown in FIG. 7, the extension members 310A, 310B, 310C, and 310D may be formed along the edge of the showerhead 300 to extend upward. Third coupling holes 330 to which the aforementioned supports 190, 192, and 194 are coupled may be formed in the extension members 310A, 310B, 310C, and 310D.

The extension members 310A, 310B, 310C, and 310D may be respectively inserted into and connected to the openings 110A, 110B, 110C, and 110D formed through the backing plate 100 in a vertical direction. In this case, the extension members 310A, 310B, 310C, and 310D may be connected to the openings 110A, 110B, 110C, and 110D to accommodate thermal expansion when the showerhead 300 thermally expands.

FIG. 8 is a side cross-sectional view of the large sized showerhead assembly 1000 of FIG. 6 and shows a connection structure of the extension member 310C and the opening 110C.

Referring to FIG. 8, the extension member 310C of the showerhead 300 may be inserted into the opening 110C of the backing plate 100. In this case, the support 190 may be coupled to the third coupling hole 330 formed in the extension member 310C through a third through hole 130 formed in the side wall 102 of the backing plate 100 to fix the showerhead 300 to the backing plate 100.

The support 190 may be formed as a bolt, a screw, or the like and, in this case, as shown in FIG. 8, a screw thread 191 may be formed on an end portion of the support 190. That is, the support 190 may not be coupled to the third through hole 130 formed in the side wall 102 of the backing plate 100 but be coupled to the third coupling hole 330 formed in the extension member 310C through the third through hole 130. Accordingly, the support 190 may be connected to the backing plate 100 to withstand the weight of the showerhead 300 and to also allow the extension member 310C moveably fixed.

In this case, the opening 110C may be formed with a larger volume than that of the extension member 310C. That is, the opening 110C may be formed with a larger volume than that of the extension member 310C to have a space in which the extension member 310C is capable of being moved.

For example, as shown in FIG. 8, when the extension member 310C of the showerhead 300 is inserted into the opening 110C of the backing plate 100, a predetermined space may be formed with a fifth separation distance d₅ between an external side surface of the extension member 310C and an internal side surface of the opening 110C. Accordingly, when the extension member 310C is moved due to thermal expansion of the showerhead 300, the extension member 310C may be moved in the space formed in the opening 110C.

Differently from the aforementioned embodiment, according to the present embodiment, RF power may not be applied to the backing plate 100 but be applied directly to the showerhead 300.

In detail, RF power may be applied directly to an end portion of the extension members 310A and 310C positioned through the openings 110A and 110C. In this case, differently from the aforementioned embodiment, RF power is applied directly to the showerhead 300 without passing through the backing plate 100 and, thus, transmission efficiency of RF power may be relatively increased. In addition, RF power may be supplied through an end surface of the end portion of the extension members 310A and 310C and, thus, may be more effectively supplied.

In the present embodiment, an interval adjuster unit 196 may also be used.

In addition, a fourth coupling hole 101 may be formed in a lower end portion of the side wall 102 of the backing plate 100 in a perpendicular direction thereto and a fourth through hole 301 may be formed in the showerhead 300. That is, the interval adjuster unit 196 may be coupled and connected only to the fourth coupling hole 101 through the fourth through hole 301. In this case, to allow a volume change of the showerhead 300 due to thermal expansion, the fourth through hole 301 may be formed as a longitudinal hole to have a larger internal space in a horizontal direction than the interval adjuster unit 196 as shown in the drawing. Accordingly, even if the showerhead 300 thermally expands, the volume change of the showerhead 300 may be allowed due to the internal space of the fourth through hole 301 without interfering with the interval adjuster unit 196.

When the interval adjuster unit 196 is fastened to be coupled to the aforementioned fourth coupling hole 101, the showerhead 300 may be moved upward by the interval adjuster unit 196. In this case, a lower end surface 103 of the side wall 102 of the backing plate 100 may be spaced apart from an upper end surface 302 of the showerhead 300 by a predetermined interval. Accordingly, the showerhead 300 may be moved upward without interfering with the backing plate 100. When the interval adjuster unit 196 is unfastened, the showerhead 300 may be moved downward.

Accordingly, the interval adjuster unit 196 may be fastened or unfastened to narrow or widen an interval between the showerhead 300 and a substrate.

To allow the interval adjuster unit 196 to adjust the interval, the third through hole 130 of the backing plate 100 with the aforementioned support 190 inserted thereinto may be formed in the form of a longitudinal hole.

In addition, the support 190 may be arranged in a direction in which the showerhead 300 thermally expands, which is similar to the aforementioned embodiment.

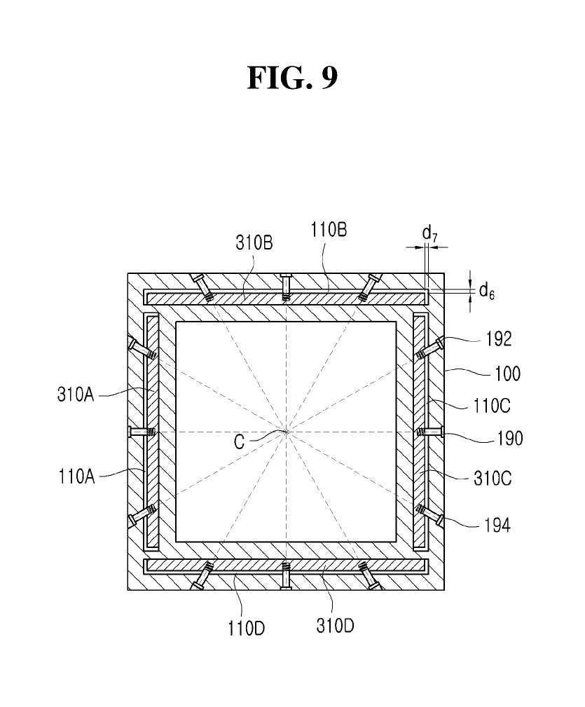

FIG. 9 is a transverse cross-sectional view of the large sized showerhead assembly 1000. For convenience of description of FIG. 9, only the supports 190, 192, and 194 for connecting one extension member 310C to one opening 110C will be described below.

Referring to FIG. 9, when the supports 190, 192, and 194 connect the extension member 310C to the opening 110C moveably fixed, the supports 190, 192, and 194 may be radially arranged around the central portion C of the showerhead 300. In this case, the aforementioned first support may include a first support 192 and second supports 192 and 194.

For example, the aforementioned first support 190 and second supports 192 and 194 may be arranged along an imaginary line that radially extends in a radial direction from the central portion C of the showerhead 300. Accordingly, when the showerhead 300 is radially deformed around the central portion C due to thermal expansion, the extension member 310C may be prevented from being damaged or deformed by the first support 190 and the second supports 192 and 194.

The first support 190 and the second supports 192 and 194 may guide a volume change due to thermal expansion when the showerhead 300 thermally expands and may also prevent the showerhead 300 from sagging, but are different in terms of a main function.

That is, with regard to the first support 190 and the second supports 192 and 194, the first support 190 may be coupled to the extension member 310C in a perpendicular direction thereto and the second supports 192 and 194 may be coupled to the extension member 310C to be angled therewith at a predetermined angle. Accordingly, a main function of the first support 190 may be guidance of a volume change due to thermal expansion when the showerhead 300 thermally expands and a main function of the second supports 192 and 194 may be prevention of the showerhead 300 from sagging.

Thus far, although only the supports 190, 192, and 194 for connecting one extension member 310C to one opening 110C have been described, the present invention is not limited thereto and, thus, supports for connecting the other extension members 310A, 310B, and 310D to the openings 110A, 110B, and 110D may also be configured.

When the showerhead 300 is deformed due to thermal expansion, the showerhead 300 may be deformed in both horizontal and vertical directions. Accordingly, when there is a separation distance between an external side surface of the extension members 310A, 310B, 310C, and 310D and an internal side surface of the openings 110A, 110B, 110C, and 110D, a seventh separation distance d₇ as well as a sixth separation distance d₆ may be formed. Accordingly, when one extension member is moved in one opening due to thermal expansion, the extension member may be capable of being moved in both horizontal and vertical directions.

According to the present invention, when a showerhead that is large-sized and has a large area is connected to a backing plate, the showerhead may allow a volume change due to thermal expansion without sagging while being fixedly connected to the backing plate.

The foregoing exemplary embodiments and advantages are merely exemplary and are not to be construed as limiting the present invention. The present teaching can be readily applied to other types of apparatuses. Also, the description of the exemplary embodiments of the present invention is intended to be illustrative, and not to limit the scope of the claims, and many alternatives, modifications, and variations will be apparent to those skilled in the art.

What is claimed is:

1. A large sized showerhead assembly comprising:
a backing plate disposed in a chamber; and
a showerhead disposed below the backing plate to supply gas toward a substrate,
wherein the showerhead is connected to the backing plate to thermally expand.

2. The large sized showerhead assembly of claim 1, further comprising a connecting unit that connects the showerhead to the backing plate,
wherein the showerhead comprises an extension member that extends upward along an edge of an upper surface of the showerhead and the extension member is inserted into the connecting unit and the extension member is connected to the connecting unit to thermally expand to support the showerhead.

3. The large sized showerhead assembly of claim 2, wherein the connecting unit connects the extension member to the backing plate in a lateral direction of the backing plate.

4. The large sized showerhead assembly of claim 3, wherein the connecting unit comprises:
a groove portion into which the extension member is inserted and which has a greater internal volume than a size of the extension member to allow the extension member to accommodate thermal expansion of the showerhead; and
a support which has an end portion fixed to the extension member through a first through hole of a side wall of the backing plate to support the extension member.

5. The large sized showerhead assembly of claim 4, wherein the support comprises:
a first support coupled to the extension member in a perpendicular direction thereto and configured to guide a volume change due to thermal expansion of the extension member; and
a second support coupled to the extension member to be angled therewith at a predetermined angle and configured to prevent the showerhead from sagging.

6. The large sized showerhead assembly of claim 4, wherein the support comprises a screw or a bolt and has a screw thread that is formed on an end portion of the support and is coupled to the extension member through the first through hole of the side wall of the backing plate.

7. The large sized showerhead assembly of claim 4, wherein the first through hole is formed as a longitudinal hole in a vertical direction.

8. The large sized showerhead assembly of claim 4, wherein the support comprises a circular or curved head formed on an end portion thereof; and
wherein the extension member comprises an insertion space with the head inserted thereinto and having a larger volume than a size of the head.

9. The large sized showerhead assembly of claim 4, wherein the support is radially arranged around a central portion of the showerhead.

10. The large sized showerhead assembly of claim 4, wherein radio frequency (RF) power is applied to the backing plate; and
wherein the large sized showerhead assembly further comprises a fixing member that is formed on a central portion of the showerhead and connects the backing plate to the showerhead to support the showerhead and to transmit the RF power applied to the backing plate to the showerhead.

11. The large sized showerhead assembly of claim 3, wherein the connecting unit comprises:
an opening through which the extension member is disposed and which has a larger volume than a size of the extension member to accommodate thermal expansion of the showerhead; and
a support which has an end portion fixed to the extension member through a through hole of a side wall of the backing plate to support the extension member.

12. The large sized showerhead assembly of claim 11, wherein the support comprises:
a first support coupled to the extension member in a perpendicular direction thereto and configured to guide a volume change due to thermal expansion of the extension member; and
a second support coupled to the extension member to be angled therewith at a predetermined angle and configured to prevent the showerhead from sagging.

13. The large sized showerhead assembly of claim 11, wherein the support comprises a screw or a bolt and has a screw thread that is formed on an end portion of the support and is coupled to the extension member through a side wall of the backing plate.

14. The large sized showerhead assembly of claim 11, wherein the through hole is formed as a longitudinal hole in a vertical direction.

15. The large sized showerhead assembly of claim 11, wherein the support comprises a circular or curved head formed on an end portion thereof; and
wherein the extension member comprises an insertion space with the head inserted thereinto and having a larger volume than a size of the head.

16. The large sized showerhead assembly of claim 11, wherein the support is radially arranged around a central portion of the showerhead.

17. The large sized showerhead assembly of claim 11, wherein RF power is directly applied to the extension member positioned through the opening.

18. The large sized showerhead assembly of claim 3, wherein the connecting unit further comprises an interval adjuster unit configured to adjust an interval between the showerhead and the substrate.

19. The large sized showerhead assembly of claim 18, wherein the interval adjuster unit comprises a screw or a bolt and is coupled to the backing plate through a bottom surface of the showerhead.

20. The large sized showerhead assembly of claim 19, wherein the showerhead comprises a through hole formed therein;
wherein the interval adjuster unit is coupled to a lower end portion of a side wall of the backing plate through the through hole; and
wherein the through hole is formed as a longitudinal direction in a horizontal direction.
